(19) United States
(12) Patent Application Publication
(10) Pub. No.: US 2016/0067996 A1
(43) Pub. Date: Mar. 10, 2016

(54) METHOD FOR FORMING PATTERN ON SURFACE OF INSULATING SUBSTRATE AND CERAMIC ARTICLE

(71) Applicant: BYD COMPANY LIMITED, Shenzhen (CN)

(72) Inventors: Qiang XU, Shenzhen (CN); Xinping LIN, Shenzhen (CN)

(73) Assignee: BYD COMPANY LIMITED

(21) Appl. No.: 14/943,808

(22) Filed: Nov. 17, 2015

Related U.S. Application Data
(63) Continuation of application No. PCT/CN2014/078067, filed on May 21, 2014.

(30) Foreign Application Priority Data
May 23, 2013 (CN) 201310196544.5

(51) Int. Cl. B41M 5/26; B41M 5/24; C23C 14/35

(52) U.S. Cl. CPC B41M 5/262; C23C 14/35; B41M 5/24

(57) ABSTRACT

Embodiments of the present disclosure are directed to a method for forming a pattern on a surface of an insulating substrate and/or a ceramic article. The method comprises: forming a film on at least one surface of the insulating substrate, a material of the film comprising at least one of ZnO, SnO₂, TiO₂, or a combination thereof; and irradiating at least a part of the film by an energy beam to form the pattern in the film.

### CROSS-REFERENCE TO RELATED APPLICATION

This application is a continuation of International Application No. PCT/CN2014/078067, filed May 21, 2014, which claims priority to and benefits of Chinese Patent Application Serial No. 201310196544.5, filed with the State Intellectual Property Office of P. R. China on May 23, 2013. Both of the above referenced applications are incorporated herein by reference in their entirety.

### FIELD

The present disclosure relates to a method for forming a pattern on a surface of an insulating substrate and a ceramic article.

### BACKGROUND

A laser marking technology is a method for forming a permanent mark by locally irradiating a workpiece using a laser with a high energy density so as to vaporize or change a color of the material from the surface of the workpiece.

However, for ceramic or a white ceramic (such as an alumina ceramic and a zirconia ceramic), which has a poor absorption for light from a laser, it is difficult to mark with a low energy laser (such as a laser with a wavelength of 1064 nm and a power of 20 W). Although it is possible to form a pattern on such a white ceramic by employing a laser with a higher energy, in one aspect the pattern usually has a poor precision, and in another aspect a marking cost is correspondingly increased by employing the laser with a higher energy. Therefore, currently an additive, which may facilitate the absorption for the light from a laser may be added to a ceramic substrate prior to the laser marking. However, an intrinsic property (such as a microstructure and a color) of the ceramic substrate can be affected by the additives.

Therefore, there is a need for a method for forming a pattern on a surface of an insulating substrate, especially a white ceramic substrate, which may not affect the intrinsic property of the ceramic substrate, and may be implemented with a low energy laser.

### SUMMARY

According to a first aspect of the present disclosure, a method for forming a pattern on a surface of an insulating substrate is provided. The method comprises: forming a film on at least one surface of the insulating substrate, a material of the film comprising any one of ZnO, SnO₂, TiO₂, or a combination thereof; and irradiating at least a part of the film by an energy beam to form the pattern in the film.

With the method for forming the pattern on the surface of the insulating substrate according to embodiments of the present disclosure, an intrinsic property (such as a microstructure and a color) of the insulating substrate is not affected because no additive, which may facilitate an absorption for the energy beam, is added to the insulating substrate. Moreover, the film formed by the method according to embodiments of the present disclosure has such a light color that the intrinsic color of the insulating substrate will not be covered. Last but not the least, the film has a high absorption for the energy beam, such that the film may be patterned even with a low energy beam (such as a laser with a wavelength of 1064 nm and a power of 20 W). Thus, the method according to embodiments of the present disclosure may be used to form a high precision marking (such as a pattern or a circuit) on the surface of the insulating substrate, especially a ceramic substrate.

According to a second aspect of the present disclosure, a ceramic article is provided. The ceramic article comprises: a ceramic substrate; and a film with a pattern formed on at least one surface of the ceramic substrate, wherein a material of the film is selected from a group consisting of ZnO, SnO₂, TiO₂, and a combination thereof.

With the ceramic article according to embodiments of the present disclosure, not only a pattern is formed on the surface of the ceramic substrate, but also an intrinsic property of the ceramic substrate is substantially maintained.

Additional aspects and advantages of embodiments of present disclosure will be given in part in the following descriptions, become apparent in part from the following descriptions, or be learned from the practice of the embodiments of the present disclosure.

### DETAILED DESCRIPTION

Reference will be made in detail to embodiments of the present disclosure. The embodiments described herein are explanatory, illustrative, and used to generally understand the present disclosure. The embodiments shall not be construed to limit the present disclosure.

According to embodiments of the present disclosure, a method for forming a pattern on a surface of an insulating substrate is provided. The method comprises following steps.

At step S1, a film is formed on at least one surface of the insulating substrate. A material of the film is selected from a group consisting of ZnO, SnO₂, TiO₂, and a combination thereof.

In one embodiment, the material of the film may comprise ZnO and/or SnO₂.

In one embodiment, the material of the film may comprise a first material and a second material. The first material comprises ZnO and/or SnO₂, and the second material comprises TiO₂. In some embodiments, the film has an enhanced absorption for the energy beam, such that the energy beam with a low energy may be employed to irradiate the film in a next step to form a high precision pattern. A relative ratio between the first material and the second material depends on an intensity of the energy beam. For example, a content of the first material in the film may range from 50 wt % to 99 wt %, while a content of the second material in the film may range from 1 wt % to 50 wt %. In such embodiments, a film with a high precision pattern and good chemical plating activity and/or rate can be formed even by using a low energy beam. In another embodiment, the content of the first material in the film may range from 80 wt % to 99 wt %, while the content of the second material in the film may range from 1 wt % to 20 wt %, and the film formed in this way may have a higher chemical plating rate and/or an improved adhesive force. In yet another embodiment, the content of the first material in the film may range from 85 wt % to 95 wt %, while the content of the second material in the film may range from 5 wt % to 15 wt %, so that the film has a color closer to an intrinsic color of the insulating substrate, has an enhanced absorption for the energy beam, as well as may achieve a higher chemical plating rate during a subsequent chemical plating process.

In one embodiment, the first material and the second material may be formed in one layer of film. Alternatively, the first material and the second material may be formed in different layers of film, which are adjacent to each other.

A thickness of the film, which is not limited herein, may depend on a practical application. In some embodiments, the thickness of the film usually ranges from 1 μm to 100 μm. In some embodiments, the thickness of the film ranges from 5 μm to 30 μm. In some embodiments, a total thickness of multiple layers of the film may also range from 1 μm to 100 μm. In some embodiments, a total thickness of multiple layers of the film may range from 5 μm to 30 μm.

In one embodiment, the film may be formed on at least one surface of the insulating substrate by various processes, such as chemical vapor deposition (CVD) and magnetron sputtering. The film formed by magnetron sputtering has advantages of uniform thickness, high adhesive force, and good controllability of a film-forming process.

In one embodiment, the material containing at least one of ZnO, SnO₂, and TiO₂ is directly deposited on the at least one surface of the insulating substrate to form the film. Alternatively, precursors of above oxides may be firstly deposited on the at least one surface of the insulating substrate and then oxidized to form the film. The precursors are not specifically limited herein. For example, one or more metal selected from Zn, Sn, and Ti may be deposited on the at least one surface of the insulating substrate and then oxidized in an atmosphere containing oxygen to form the film. In one embodiment, an oxidation process may be performed at a temperature ranging from 950° C. to 1500° C. and last for 1 hour to 6 hours.

In one embodiment, the film is formed by magnetron sputtering under a condition of a vacuum with a pressure ranging from 6×10⁻³ Pa to 1×10⁻⁴ Pa, a voltage ranging from 370V to 500V, an electric current ranging from 12 A to 17 A, and an argon atmosphere. During the magnetron sputtering, oxygen is required to charge into a sputtering chamber to form the oxide film.

The film may comprise a single layer or multiple layers, such as two layers or three layers. In the case of multiple layers, the materials of individual layers may be identical to or different from each other. In one embodiment, the materials of individual layers are different from each other such that performances and/or properties of the multiple layers may be complementary to each other.

In one embodiment, a second film (comprising TiO₂) is formed on a first film (comprising ZnO and/or SnO₂), so as to further improve the absorption of the second film for the energy beam. In this case, the thickness of the second film and the thickness of the first film are selected such that of the total content of the films, a content of the first film may range from 50 wt % to 99 wt %, e.g., from 80 wt % to 99 wt % or from 85 wt % to 95 wt %, while a content of the second film may range from 1 wt % to 50 wt %, e.g., from 1 wt % to 20 wt % or from 5 wt % to 15 wt %.

With the method for forming the pattern on the surface of the insulating substrate according to embodiments of the present disclosure, the intrinsic property of the insulating substrate is not affected. The insulating substrate may be an organic substrate or an inorganic substrate, including but not limited to a polymer substrate, a paper substrate, a glass substrate, and a ceramic substrate. In one embodiment, the insulating substrate is a ceramic substrate, e.g., a white ceramic substrate (such as an alumina ceramic substrate and a zirconia ceramic substrate).

At step S2, at least a part of the film is irradiated by the energy beam to form the pattern in the film. A transition occurs to atoms of the material of the film irradiated under an action of the energy beam from a ground state to an excited state, and energy is thus released when the transited atoms return to the ground state, such that the material from a surface of the film irradiated is melted and even vaporized, and thus the color of the film is changed and the pattern is accordingly formed.

In some embodiments, the energy beam may be a laser, an electronic beam, or an ion beam. In one embodiment, the energy beam is a laser with a wavelength ranging from 200 nm to 3000 nm, a power ranging from 5 W to 3000 W, and a frequency ranging from 0.1 KHz to 200 KHz. In another embodiment, the energy beam is an electronic beam with a power density ranging from 10 W/cm² to 10¹¹ W/cm². In yet another embodiment, the energy beam is an ion beam with an energy ranging from 10 eV to 10⁶ eV. In one embodiment, the energy beam is a laser with a wavelength ranging from 532 nm to 1064 nm and a power ranging from 20 W to 100 W.

With the method according to embodiments of the present disclosure, the film has a high absorption for the energy beam, such that the film may be patterned even with a low energy beam, such as a laser with a wavelength ranging from 532 nm to 1064 nm and a power ranging from 20 W to 30 W, e.g., a laser with a wavelength of 1064nm and a power ranging from 20 W to 30 W.

If the laser is employed to irradiate the film, the laser may be generated by any type of laser device, such as a YAG laser, a green light laser, and a fiber laser. In some embodiments, a scanning speed of the laser may range from 0.01 mm/s to 50000 mm/s, e.g., from 50 mm/s to 150 mm/s, and a gap distance may range from 0.01 mm to 5 mm, e.g., from 0.02 mm to 1 mm.

Alternatively or additionally, if the insulating substrate is a ceramic substrate, the method further comprises sintering the ceramic substrate prior to step S2, such that an adhesive force between the film and the substrate may be enhanced. If the film comprises multiple layers, the sintering may increase diffusions between respective layers of materials, thus may further improve the absorption for the energy beam. For example, in the case of the second film (comprising TiO₂) formed on the first film (comprising ZnO and/or SnO₂), the absorption of the second film for the energy beam is substantially improved by the sintering.

Parameters of the sintering depend on materials of the substrate and the film. In some embodiments, the sintering may be performed at a temperature ranging from 950° C. to 1500° C. and may last for 1 hour to 6 hours. The sintering may be performed in an atmosphere containing oxygen or a nonreactive atmosphere (such as nitrogen and gases of group 0 elements), e.g., in the atmosphere containing oxygen, such that an adhesive force between a chemical plating layer formed subsequently and the film is enhanced. In some embodiments, the atmosphere containing oxygen may be, for example, an air atmosphere or an atmosphere of a mixture of oxygen and a nonreactive gas. In one embodiment, the sintering process and the oxidation process described above may be performed simultaneously.

With the method according to embodiment of the present disclosure, by using the energy beam to irradiate the film, not only a high precision pattern may be formed in the film, but also the chemical plating activity of the film irradiated may be excited, such that a metal layer may be formed on the pattern by chemical plating so as to further form a metallic pattern or a high precision circuit. Therefore, in some embodiments, after step S2, a chemical plating step may be further performed on the substrate to form at least one metal layer on the pattern. For example, after the irradiation, the substrate is immersed into a copper plating solution containing a cupric salt and a reducing agent with a pH of 12-13. Copper ions in the cupric salt may be reduced to a copper simple substance by the reducing agent. The reducing agent may be selected from a group consisting of glyoxylic acid, hydrazine, sodium hypophosphite, and a combination thereof. In this way, a copper layer is formed on the pattern.

A thickness of the metal layer may depend on a function and/or property of the metal layer and thus it is not limited herein.

In one embodiment, after the chemical plating step described above, an electroplating or one or more chemical plating steps may be additionally performed to increase a thickness of a plating layer or form another metal layer on the chemical plating layer. For example, a nickel layer may be formed on the copper layer to reduce or prevent oxidization.

According to embodiments of the present disclosure, a ceramic article is provided. The ceramic article comprises: a ceramic substrate; and a film with a pattern formed on at least one surface of the ceramic substrate. A material of the film is selected from a group consisting of ZnO, SnO₂, TiO₂, and a combination thereof.

The ceramic substrate may be any ceramic substrate. In one embodiment, the ceramic substrate may be an alumina ceramic substrate or a zirconia ceramic substrate.

In one embodiment, the material of the film may comprise ZnO and/or SnO₂.

In one embodiment, the material of the film may comprise a first material and a second material. The first material comprises ZnO and/or SnO₂, and the second material comprises TiO₂. In this case, a relative ratio between the first material and the second material depends on an intensity of the energy beam. For example, a content of the first material in the film may range from 50 wt % to 99 wt %, while a content of the second material in the film may range from 1 wt % to 50 wt %. In another embodiment, the content of the first material in the film may range from 80 wt % to 99 wt %, while the content of the second material in the film may range from 1 wt % to 20 wt %. In yet another embodiment, the content of the first material in the film may range from 85 wt % to 95 wt %, while the content of the second material in the film may range from 5 wt % to 15 wt %.

In one embodiment, the first material and the second material may be formed in one layer of the film. Alternatively, the first material and the second material may be formed in different layers of the film that are adjacent to each other.

The film may comprise a single layer or multiple layers, such as two layers or three layers. In the case of multiple layers, the materials of individual layers may be identical to or different from each other. In one embodiment, the materials of individual layers are different from each other such that performances and/or properties of the multiple layers may be complementary to each other.

In one embodiment, a second film (comprising TiO₂) is formed on a first film (comprising ZnO and/or SnO₂). In this case, of the total content of the films, a content of the first film may range from 50 wt % to 99 wt %, while a content of the second film may range from 1 wt % to 50 wt %. For example, the content of the first film may range from 80 wt % to 99 wt %, while the content of the second film in the film may range from 1 wt % to 20 wt %. For another example, the content of the first film may range from 85 wt % to 95 wt %, while the content of the second film in the film may range from 5 wt % to 15 wt %.

A thickness of the film usually ranges from 1 μm to 100 μm, e.g., from 5 μm to 30 μm. A total thickness of multiple layers of the film may range from 1 μm to 100 μm, e.g., from 5 μm to 30 μm.

In one embodiment, the ceramic article further comprises at least one metal layer (such as a copper layer) formed on the pattern. A thickness of the metal layer may depend on a function and/or property of the metal layer and thus it is not limited herein.

The ceramic article is fabricated by the method described above according to embodiments of the present disclosure.

In order to make those skilled in the art better understand the present disclosure, a series of examples and comparative examples are illustrated below, in which the adhesive force of the metal layer formed on the film was measured using a BYK process disclosed in ISO 2409. Firstly, a 10×10 grid (including 1 mm×1 mm test regions) was formed on a surface of a sample by using a BYK knife and the scraps were cleaned up, in which each cross-cut line reached a bottom of the metal layer. Secondly, an adhesive tape (such as adhesive paper 3M600) was attached to a region to be tested and then was torn off by holding one end of the adhesive tape and quickly moving in a direction perpendicular to the surface of the sample. Such a measurement was carried out twice at a same position, and a level of the adhesive force of the metal layer was thus determined according to following criterions.

ISO level 0: an edge of a cross-cut line is smooth and there is no metal falling off at both edges and intersections of the cross-cut lines.

ISO level 1: there is a small piece of metal falling off at the intersections of the cross-cut lines and an area of the small piece(s) is less than 5% of a total area of the metal layer.

ISO level 2: there are small pieces of metal falling off at both the edges and intersections of the cross-cut lines and an area of the small pieces ranges from 5% to 15% of the total area of the metal layer.

ISO level 3: there are pieces of metal falling off at both the edges and intersections of the cross-cut lines and an area of the pieces ranges from 15% to 35% of the total area of the metal layer.

ISO level 4: there are pieces of metal falling off at both the edges and intersections of the cross-cut lines and an area of the pieces ranges from 35% to 65% of the total area of the metal layer.

ISO level 5: there are pieces of metal falling off at both the edges and intersections of the cross-cut lines and an area of the pieces is greater than 65% of the total area of the metal layer.

### EXAMPLE 1

A Zn film with a thickness of 15 μm was formed on an alumina ceramic substrate (40 mm×40 mm×1 mm) by magnetron sputtering. The sample was sintered in a sintering furnace in an air atmosphere at 1300° C. for 4 hours, and then cooled. Then, at least a part of the film was irradiated by a laser to form a pattern, and a color of an irradiated region of the film was deeper than that of the remaining regions. Last, the sample was immersed into a chemical plating solution for chemical plating. A plating rate was 1.5 μm/h, and a plating layer with a thickness of 8.2 μm was ultimately formed on the patterned Zn film.

The magnetron sputtering was performed using a Zn target in a vacuum with a pressure of 8×10⁻³ Pa, a voltage of 450V, an electric current of 16 A, and an argon atmosphere.

Irradiation was performed using a YAG laser with a wavelength of 1064 nm, a power of 20 W, a frequency of 50 kHz, a scanning speed of 100 mm/s, and a gap distance of 0.05 mm.

A chemical plating solution comprised CuSO₄.5H₂O (0.12 mol/L), Na₂EDTA.2H₂O (0.14 mol/L), potassium ferrocyanide (10 mg/L), 2,2′-bipyridine (10 mg/L), and glyoxalic acid (HCOCOOH) (0.10 mol/L) with a pH of 12.5-13 adjusted by NaOH and H₂SO₄ solutions, and with water as a solvent.

The adhesive force and the color of the Zn film were measured. An adhesive force between the Zn film and the substrate was ISO level 2 before sintering and was ISO level 0 after sintering; the color of the Zn film was light grey (i.e., with a hexadecimal color code of #D3D3D3, and a RGB color model of 211, 211, 211) before sintering and was snow (i.e., with a hexadecimal color code of #FFFAFA, and a RGB color model of 255, 250, 250) after sintering; an adhesive force between the plating layer and the Zn film was ISO level 0.

It was observed by a microscope that the lines of the pattern were in order and clear, and the metal plating layer in a patterned region (i.e., on the pattern) was continuous and uniform.

### COMPARATIVE EXAMPLE 1

This example was performed by using substantially the same method as that described in Example 1 except that the alumina ceramic substrate was directly irradiated by the laser without forming the Zn film thereon. As a result, the color of the irradiated region of the film did not change and there was no metal plating layer formed on the substrate.

### COMPARATIVE EXAMPLE 2

This example was performed by using substantially the same method as that used in Comparative Example 1 except that the irradiation was performed using a YAG laser with a wavelength of 1064 nm, a power of 50 W, a frequency of 50 kHz, a scanning speed of 100 mm/s, and a gap distance of 0.05 mm.

It was observed by the microscope that edges of the lines of the pattern were rough and uneven, and the metal plating layer in a patterned region (i.e., on the pattern) was discontinuous.

### EXAMPLE 2

A Sn film with a thickness of 20 μm was formed on an alumina ceramic substrate (40 mm×40 mm×1 mm) by magnetron sputtering. The sample was sintered in a sintering furnace in an air atmosphere at 1300° C. for 4 hours, and then cooled. Then, at least a part of the film was irradiated by a laser to form a pattern, and a color of an irradiated region of the film was deeper than that of the remaining regions. Last, the sample was immersed into a chemical plating solution for chemical plating. A plating rate was 1.6 μm/h, and a plating layer with a thickness of 9.4 μm was ultimately formed on the patterned Sn film.

The magnetron sputtering was performed using a Sn target in a vacuum with a pressure of 9×10⁻³ Pa, a voltage of 430 V, an electric current of 16 A, and an argon atmosphere.

Irradiation was performed using a YAG laser with a wavelength of 1064 nm, a power of 20 W, a frequency of 50 kHz, a scanning speed of 100 mm/s, and a gap distance of 0.05 mm.

The chemical plating solution was the same as that used in Example 1.

The adhesive force and the color of the Sn film were measured. An adhesive force between the Sn film and the substrate was ISO level 2 before sintering and was ISO level 0 after sintering; the color of the Sn film was light grey (i.e., with a hexadecimal color code of #D3D3D3, and a RGB color model of 211, 211, 211) before sintering and was ivory (i.e., with a hexadecimal color code of #FFFFF0, and a RGB color model of 255, 255, 240) after sintering; an adhesive force between the plating layer and the Sn film was ISO level 0.

It was observed by the microscope that the lines of the pattern were in order and clear, and the metal plating layer in a patterned region (i.e., on the pattern) was continuous and uniform.

### EXAMPLE 3

A Zn film with a thickness of 18 μm was formed on a zirconia ceramic substrate (40 mm×40 mm×1 mm) by magnetron sputtering. The sample was sintered in a sintering furnace in an air atmosphere at 1100° C. for 5 hours, and then cooled. Then, at least a part of the film was irradiated by a laser to form a pattern, and a color of an irradiated region of the film was deeper than that of the remaining regions. Last, the sample was immersed into a chemical plating solution for chemical plating. A plating rate was 1.7 μm/h, and a plating layer with a thickness of 8.6 μm was ultimately formed on the patterned Zn film.

The magnetron sputtering was performed using a Zn target in a vacuum with a pressure of 7×10⁻³ Pa, a voltage of 440 V, an electric current of 15 A, and an argon atmosphere.

Irradiation was performed using a YAG laser with a wavelength of 1064 nm, a power of 20 W, a frequency of 50 kHz, a scanning speed of 100 mm/s, and a gap distance of 0.05 mm.

A chemical plating solution comprised copper acetate (10 g/L), ethylenediamine tetraacetic acid (EDTA) (25 g/L), formaldehyde (10 mL/L), sodium potassium tartrate (15 g/L), and fluoroboric acid (50 g/L) with a pH of 12 adjusted by a solution of NaOH (with a concentration of 50 wt %), and water as a solvent.

The adhesive force and the color of the Zn film were measured. An adhesive force between the Zn film and the substrate was ISO level 3 before sintering and was ISO level 0 after sintering; the color of the Zn film was light grey (i.e., with a hexadecimal color code of #D3D3D3, and a RGB color model of 211, 211, 211) before sintering and was snow (i.e., with a hexadecimal color code of #FFFAFA, and a RGB color model of 255, 250, 250) after sintering; an adhesive force between the plating layer and the Zn film was ISO level 0.

It was observed by the microscope that the lines of the pattern were in order and clear, and the metal plating layer in a patterned region (i.e., on the pattern) was continuous and uniform.

### COMPARATIVE EXAMPLE 3

This example was performed by using substantially the same method as that described in Example 3 except that the zirconia ceramic substrate was directly irradiated by the laser without forming the Zn film thereon. As a result, the color of the irradiated region of the film did not change and there was no metal plating layer formed on the substrate.

### COMPARATIVE EXAMPLE 4

This example was performed by using substantially the same method as that in Comparative Example 3 except that the irradiation was performed using a YAG laser with a wavelength of 1064 nm, a power of 50 W, a frequency of 50 kHz, a scanning speed of 100 mm/s, and a gap distance of 0.05 mm.

It was observed by the microscope that edges of the lines of the pattern were rough and uneven, and the metal plating layer in a patterned region (i.e., on the pattern) was discontinuous.

### EXAMPLE 4

A Sn film with a thickness of 25 μm was formed on a zirconia ceramic substrate (40 mm×40 mm×1 mm) by magnetron sputtering. The sample was sintered in a sintering furnace in an air atmosphere at 1500° C. for 2 hours, and then cooled. Then, at least a part of the film was irradiated by a laser to form a pattern, and a color of an irradiated region of the film was deeper than that of the remaining regions. Last, the sample was immersed into a chemical plating solution for chemical plating. A plating rate was 1.6 μm/h, and a plating layer with a thickness of 8.8 μm was ultimately formed on the patterned Sn film.

The magnetron sputtering was performed using a Sn target in a vacuum with a pressure of 8×10⁻³ Pa, a voltage of 450 V, an electric current of 16 A, and an argon atmosphere.

Irradiation was performed using a YAG laser with a wavelength of 1064 nm, a power of 20 W, a frequency of 50 kHz, a scanning speed of 150 mm/s, and a gap distance of 0.05 mm.

A chemical plating solution was the same as that used in Example 1.

The adhesive force and the color of the Sn film were measured. An adhesive force between the Sn film and the substrate was ISO level 2 before sintering and was ISO level 0 after sintering; the color of the Sn film was light grey (i.e., with a hexadecimal color code of #D3D3D3, and a RGB color model of 211, 211, 211) before sintering and was ivory (i.e., with a hexadecimal color code of #FFFFF0, and a RGB color model of 255, 255, 240) after sintering; an adhesive force between the plating layer and the Sn film was ISO level 0.

It was observed by the microscope that the lines of the pattern were in order and clear, and the metal plating layer in a patterned region (i.e., on the pattern) was continuous and uniform.

### EXAMPLE 5

A ZnO film with a thickness of 15 μm was formed on an alumina ceramic substrate (40 mm×40 mm×1 mm) by magnetron sputtering. The sample was sintered in a sintering furnace in an air atmosphere at 950° C. for 6 hours, and then cooled. Then, at least a part of the film was irradiated by a laser to form a pattern, and a color of an irradiated region of the film was deeper than that of remaining regions. Last, the sample was immersed into a chemical plating solution for chemical plating. A plating rate was 1.6 μm/h, and a plating layer with a thickness of 8.4 μm was ultimately formed on the patterned ZnO film.

The magnetron sputtering was performed using a Zn target in a vacuum with a pressure of 8×10⁻³ Pa, a voltage of 440 V, an electric current of 17 A, and an atmosphere containing oxygen and argon with a volume ratio of 4:16.

Irradiation was performed using a YAG laser with a wavelength of 1064 nm, a power of 20 W, a frequency of 50 kHz, a scanning speed of 100 mm/s, and a gap distance of 0.05 mm.

A chemical plating solution was the same as that used in Example 1.

The adhesive force and the color of the ZnO film were measured. An adhesive force between the ZnO film and the substrate was ISO level 2 before sintering and was ISO level 0 after sintering; the color of the ZnO film was white (i.e., with a hexadecimal color code of #FFFFFF, and a RGB color model of 255, 255, 255) before sintering and was white (i.e., with a hexadecimal color code of #FFFFFF, and a RGB color model of 255, 255, 255) after sintering; an adhesive force between the plating layer and the ZnO film was ISO level 0.

It was observed by the microscope that the lines of the pattern were in order and clear, and the metal plating layer in a patterned region (i.e., on the pattern) was continuous and uniform.

### EXAMPLE 6

This example was performed by using substantially the same method as that described in Example 5 except that the substrate with the ZnO film thereon was directly irradiated by the laser without sintering, and the plating rate was 1.7 μm/h.

The adhesive force was measured. The adhesive force between the plating layer and the ZnO film was ISO level 1.

It was observed by the microscope that the lines of the pattern were in order and clear, and the metal plating layer in a patterned region (i.e., on the pattern) was continuous and uniform.

### EXAMPLE 7

This example was performed by using substantially the same method as that described in Example 5 except that the sample was sintered in a nitrogen atmosphere at 950° C. for 6 hours, and the plating rate was 1.5 μm/h.

The adhesive force and the color of the ZnO film were measured. The adhesive force between the ZnO film and the substrate was ISO level 1 after sintering; the color of the ZnO film was white (i.e., with a hexadecimal color code of #FFFFFF, and a RGB color model of 255, 255, 255) after sintering; the adhesive force between the plating layer and the ZnO film was ISO level 1.

It was observed by the microscope that the lines of the pattern were in order and clear, and the metal plating layer in a patterned region (i.e., on the pattern) was continuous and uniform.

### EXAMPLE 8

A SnO₂ film with a thickness of 20 μm was formed on an alumina ceramic substrate (40 mm×40 mm×1 mm) by magnetron sputtering. The sample was sintered in a sintering furnace in an air atmosphere at 1300° C. for 4 hours, and then cooled. Then, at least a part of the film was irradiated by a laser to form a pattern, and a color of an irradiated region of the film was deeper than that of the remaining regions. Last, the sample was immersed into a chemical plating solution for chemical plating. A plating rate was 1.5 μm/h, and a plating layer with a thickness of 8.5 μm was ultimately formed on the patterned SnO₂ film.

The magnetron sputtering was performed using a Sn target in a vacuum with a pressure of 8×10⁻³ Pa, a voltage of 450 V, an electric current of 16 A, and an atmosphere containing oxygen and argon with a volume ratio of 4:16.

Irradiation was performed using a YAG laser with a wavelength of 1064 nm, a power of 20 W, a frequency of 50 kHz, a scanning speed of 100 mm/s, and a gap distance of 0.05 mm.

A chemical plating solution was the same as that used in Example 1.

The adhesive force and the color of the SnO₂ film were measured. An adhesive force between the SnO₂ film and the substrate was ISO level 2 before sintering and was ISO level 0 after sintering; the color of the SnO₂ film was light yellow (i.e., with a hexadecimal color code of #FFFFE0, and a RGB color model of 255, 255, 224) before sintering and was snow (i.e., with a hexadecimal color code of #FFFAFA, and a RGB color model of 255, 250, 250) after sintering; an adhesive force between the plating layer and the SnO₂ film was ISO level 0.

It was observed by the microscope that the lines of the pattern were in order and clear, and the metal plating layer in a patterned region (i.e., on the pattern) was continuous and uniform.

### EXAMPLE 9

A ZnO film with a thickness of 10 μm was formed on an alumina ceramic substrate (40 mm×40 mm×1 mm) by magnetron sputtering, and then a SnO₂ film with a thickness of 15 μm was formed on the ZnO film by magnetron sputtering. The sample was sintered in a sintering furnace in an air atmosphere at 1300° C. for 4 hours, and then cooled. Then, at least a part of the film was irradiated by a laser to form a pattern, and a color of an irradiated region of the film was deeper than that of the remaining regions. Last, the sample was immersed into a chemical plating solution for chemical plating. A plating rate was 1.6 μm/h, and a plating layer with a thickness of 8.8 μm was ultimately formed on the patterned film (comprising the ZnO film and the SnO₂ film).

The magnetron sputtering for forming the ZnO film was performed using a Zn target in a vacuum with a pressure of 8×10⁻³ Pa, a voltage of 460V, an electric current of 17 A, and an atmosphere containing oxygen and argon with a volume ratio of 4:16.

The magnetron sputtering for forming the SnO₂ film was performed using a Sn target in a vacuum with a pressure of 8×10⁻³ Pa, a voltage of 460V, an electric current of 17 A, and an atmosphere containing oxygen and argon with a volume ratio of 4:16.

Irradiation was performed using a YAG laser with a wavelength of 1064 nm, a power of 20 W, a frequency of 50 kHz, a scanning speed of 100 mm/s, and a gap distance of 0.05 mm.

A chemical plating solution was the same as that used in Example 1.

The adhesive force and the color of the film were measured. An adhesive force between the film and the substrate was ISO level 2 before sintering and was ISO level 0 after sintering; the color of the film was light yellow (i.e., with a hexadecimal color code of #FFFFE0, and a RGB color model of 255, 255, 224) before sintering and was snow (i.e., with a hexadecimal color code of #FFFAFA, and a RGB color model of 255, 250, 250) after sintering; an adhesive force between the plating layer and the film was ISO level 0.

It was observed by the microscope that the lines of the pattern were in order and clear, and the metal plating layer in a patterned region (i.e., on the pattern) was continuous and uniform.

### EXAMPLE 10

A ZnO film with a thickness of 10 μm was formed on an alumina ceramic substrate (40 mm×40 mm×1 mm) by magnetron sputtering, then a TiO₂ film with a thickness of 2 μm was formed on the ZnO film by magnetron sputtering, and then a SnO₂ film with a thickness of 15 μm was formed on the TiO₂ film by magnetron sputtering. The sample was sintered in a sintering furnace in an air atmosphere at 1300° C. for 4 hours, and then cooled. Then, at least a part of the film was irradiated by a laser to form a pattern, and a color of an irradiated region of the film was deeper than that of the remaining regions. Last, the sample was immersed into a chemical plating solution for chemical plating. A plating rate was 1.2 μm/h, and a plating layer with a thickness of 8.6 μm was ultimately formed on the patterned film (comprising the ZnO film, the TiO₂ film, and the SnO₂ film, with a content of TiO₂ in the entire film being 5.3 wt %).

The magnetron sputtering for forming the ZnO film was performed using a Zn target in a vacuum with a pressure of 8×10⁻³ Pa, a voltage of 450 V, an electric current of 16 A, and an atmosphere containing oxygen and argon with a volume ratio of 4:16.

The magnetron sputtering for forming the TiO₂ film was performed using a Ti target in a vacuum with a pressure of 8×10⁻³ Pa, a voltage of 450 V, an electric current of 16 A, and an atmosphere containing oxygen and argon with a volume ratio of 4:16.

The magnetron sputtering for forming the SnO₂ film was performed using a Sn target in a vacuum with a pressure of 8×10⁻³ Pa, a voltage of 450 V, an electric current of 16 A, and an atmosphere containing oxygen and argon with a volume ratio of 4:16.

Irradiation was performed using a YAG laser with a wavelength of 1064 nm, a power of 20 W, a frequency of 50 kHz, a scanning speed of 100 mm/s, and a gap distance of 0.05 mm.

A chemical plating solution was the same as that used in Example 1.

The adhesive force and the color of the film were measured. An adhesive force between the film and the substrate was ISO level 3 before sintering and was ISO level 0 after sintering; the color of the film was light grey (i.e., with a hexadecimal color code of #D3D3D3, and a RGB color model of 211, 211, 211) before sintering and was white smoke (i.e., with a hexadecimal color code of #F5F5F5, and a RGB color model of 245, 245, 245) after sintering; an adhesive force between the plating layer and the film was ISO level 0.

It was observed by the microscope that the lines of the pattern were in order and clear, and the metal plating layer in a patterned region (i.e., on the pattern) was continuous and uniform.

### EXAMPLE 11

A ZnO film with a thickness of 10 μm was formed on an alumina ceramic substrate (40 mm×40 mm×1 mm) by magnetron sputtering, and then a TiO₂ film with a thickness of 2 μm was formed on the ZnO film by magnetron sputtering. The sample was sintered in a sintering furnace in an air atmosphere at 1300° C. for 4 hours, and then cooled. Then, at least a part of the film was irradiated by a laser to form a pattern, and a color of an irradiated region of the film was deeper than that of the remaining regions. Last, the sample was immersed into a chemical plating solution for chemical plating. A plating rate was 1.4 μm/h, and a plating layer with a thickness of 8.3 μm was ultimately formed on the patterned film (comprising the ZnO film and the TiO₂ film, with a content of TiO₂ in the entire film being 13 wt %).

The magnetron sputtering for forming the ZnO film was performed using a Zn target in a vacuum with a pressure of 8×10⁻³ Pa, a voltage of 460 V, an electric current of 18 A, and an atmosphere containing oxygen and argon with a volume ratio of 4:16.

The magnetron sputtering for forming the TiO₂ film was performed using a Ti target in a vacuum with a pressure of 8×10⁻³ Pa, a voltage of 460 V, an electric current of 18 A, and an atmosphere containing oxygen and argon with a volume ratio of 4:16.

Irradiation was performed using a YAG laser with a wavelength of 1064 nm, a power of 20 W, a frequency of 50 kHz, a scanning speed of 100 mm/s, and a gap distance of 0.05 mm.

A chemical plating solution was the same as that used in Example 1.

The adhesive force and the color of the film were measured. An adhesive force between the film and the substrate was ISO level 3 before sintering and was ISO level 0 after sintering; the color of the film was light grey (i.e., with a hexadecimal color code of #D3D3D3, and a RGB color model of 211, 211, 211) before sintering and was white (i.e., with a hexadecimal color code of #FFFFFF, and a RGB color model of 255, 255, 255) after sintering; an adhesive force between the plating layer and the film was ISO level 0.

It was observed by the microscope that the lines of the pattern were in order and clear, and the metal plating layer in a patterned region (i.e., on the pattern) was continuous and uniform.

### EXAMPLE 12

This example was performed by using substantially the same method as that described in Example 11 except that a TiO₂ film with a thickness of 12 μm was formed on the ZnO film, and the plating rate was 0.85 μm/h.

The adhesive force and the color of the film were measured. The adhesive force between the film (comprising the ZnO film and the TiO₂ film, with a content of TiO₂ in the entire film being 48 wt %) and the substrate was ISO level 3 before sintering and was ISO level 1 after sintering; the color of the film was light grey (i.e., with a hexadecimal color code of #D3D3D3, and a RGB color model of 211, 211, 211) before sintering and was white (i.e., with a hexadecimal color code of #FFFFFF, and a RGB color model of 255, 255, 255) after sintering; an adhesive force between the plating layer and the film was ISO level 2.

It was observed by the microscope that the lines of the pattern were in order and clear, and the metal plating layer in a patterned region (i.e., on the pattern) was continuous and uniform.

### EXAMPLE 13

This example was performed by using substantially the same method as that described in Example 11 except that the substrate with the ZnO film and the TiO₂ film thereon was directly irradiated by the laser without sintering, and the plating rate was 0.9 μm/h.

The adhesive force was measured. The adhesive force between the film and the substrate was ISO level 3, the adhesive force between the plating layer and the film was ISO level 2.

It was observed by the microscope that the lines of the pattern are orderly and clear, and the metal plating layer in a patterned region (i.e., on the pattern) was continuous and uniform.

Reference throughout this specification to “an embodiment,” “some embodiments,” “one embodiment”, “another example,” “an example,” “a specific example,” or “some examples,” means that a particular feature, structure, material, or characteristic described in connection with the embodiment or example is included in at least one embodiment or example of the present disclosure. Thus, the appearances of the phrases such as “in some embodiments,” “in one embodiment”, “in an embodiment”, “in another example,” “in an example,” “in a specific example,” or “in some examples,” in various places throughout this specification are not necessarily referring to the same embodiment or example of the present disclosure. Furthermore, the particular features, structures, materials, or characteristics may be combined in any suitable manner in one or more embodiments or examples.

Although explanatory embodiments have been shown and described, it would be appreciated by those skilled in the art that the above embodiments cannot be construed to limit the present disclosure, and changes, alternatives, and modifications can be made in the embodiments without departing from spirit, principles, and scope of the present disclosure.

What is claimed is:

1. A method for forming a pattern on a surface of an insulating substrate, comprising:
forming a film on at least one surface of the insulating substrate, a composition of the film comprising at least one material selected from ZnO, SnO₂, TiO₂, or a combination thereof; and
irradiating at least a part of the film by an energy beam to form the pattern in the film.

2. The method according to claim 1, wherein the composition of the film comprises ZnO and/or SnO₂.

3. The method according to claim 1, wherein
the composition of the film comprises a first material and a second material, the first material comprising ZnO and/or SnO₂, and the second material comprising TiO₂.

4. The method according to claim 3, wherein a content of the first material in the film ranges from 50 wt % to 99 wt %, and a content of the second material in the film ranges from 1 wt % to 50 wt %.

5. The method according to claim 3, wherein
the first material and the second material are formed in one layer of the film; or
the first material and the second material are formed in different layers of the film.

6. The method according to claim 5, wherein a layer of the film comprising the second material is formed on a layer of the film comprising the first material.

7. The method according to any of claims 1, wherein a thickness of the film ranges from 1 μm to 100 μm.

8. The method according to claim 1, wherein the film is formed by magnetron sputtering.

9. The method according to claims 1, wherein the insulating substrate is a ceramic substrate.

10. The method according to claim 9, wherein the ceramic substrate comprises at least one of an alumina ceramic substrate and a zirconia ceramic substrate.

11. The method according to claim 1, further comprising sintering the insulating substrate prior to the irradiation.

12. The method according to claim 11, wherein the sintering is performed at a temperature ranging from 950° C. to 1500° C. and lasts for 1 hour to 6 hours.

13. The method according to claim 1, further comprising performing chemical plating on the insulating substrate to form at least one metal layer on the pattern after the irradiation.

14. The method according to claim 1, wherein the energy beam is a laser with a wavelength ranging from 532 nm to 1064 nm and a power ranging from 20 W to 100 W.

15. A ceramic article, comprising:
a ceramic substrate; and
a film having a pattern formed on at least one surface of the ceramic substrate, wherein a composition of the film comprises at least one material selected from ZnO, SnO₂, TiO₂, or a combination thereof.

16. The ceramic article according to claim 15, further comprising at least one metal layer formed on the pattern.

17. The ceramic article according to claim 15, wherein the ceramic substrate comprises at least one of an alumina ceramic substrate and a zirconia ceramic substrate.

18. The ceramic article according to claim 15, wherein the composition of the film comprises ZnO and/or SnO₂.

19. The ceramic article according to claim 15, wherein
the composition of the film comprises a first material and a second material, the first material comprising ZnO and/or SnO₂, and the second material comprising TiO₂.

20. The ceramic article according to claim 19, wherein a content of the first material in the film ranges from 50 wt % to 99 wt %, and a content of the second material in the film ranges from 1 wt % to 50 wt %.
